(19) United States
(12) Patent Application Publication
(10) Pub. No.: US 2025/0150028 A1
(43) Pub. Date: May 8, 2025

(54) PHOTOVOLTAIC APPARATUS

(71) Applicant: SHENZHEN HELLO TECH ENERGY CO., LTD, Shenzhen (CN)

(72) Inventors: Xingchen JIANG, Shenzhen (CN); Zhongwei SUN, Shenzhen (CN); Fengwen CHEN, Shenzhen (CN); Huajun YU, Shenzhen (CN)

(21) Appl. No.: 18/810,445

(22) Filed: Aug. 20, 2024

Related U.S. Application Data
(63) Continuation of application No. PCT/CN2024/079965, filed on Mar. 4, 2024.

(30) Foreign Application Priority Data
Nov. 8, 2023 (CN) 202323022837.X

(51) Int. Cl. H02S 40/34; H02J 7/00; H02J 7/35; H02S 20/30; H02S 30/20

(52) U.S. Cl. CPC H02S 40/34; H02J 7/0047; H02J 7/35; H02S 20/30; H02S 30/20; H02J 2207/30

(57) ABSTRACT

Provided is a photovoltaic apparatus. The photovoltaic apparatus includes: a substrate; a solar cell connected to the substrate; a first electrical connector connected to the substrate; a first lead wire provided with a second electrical connector at an end of the first lead wire, the second electrical connector being configured to be removably and electrically connected to the first electrical connector; and a connection box connected to an end of the first lead wire (40) away from the second electrical connector, the connection box being configured to be electrically connected to an external device.

### CROSS-REFERENCE TO RELATED APPLICATION

This application is a continuation of International Application No. PCT/CN2024/079965, filed on Mar. 4, 2024, which claims priority to and the benefits of Chinese Patent Application No. 202323022837.X filed with China National Intellectual Property Administration on Nov. 8, 2023, which is hereby incorporated by reference in its entirety.

### FIELD

The present disclosure relates to the field of substrate technologies, and more particularly, to a photovoltaic apparatus.

### BACKGROUND

A connection box of an existing substrate is usually integrated into and connected to the substrate during designing, which makes the entire substrate unusable when the connection box is damaged.

### SUMMARY

In view of this, it is necessary to provide a photovoltaic apparatus, which can solve the problem that the entire substrate cannot be used when the connection box is damaged.

An embodiment of the present disclosure provides a photovoltaic apparatus. The photovoltaic apparatus, including a substrate; a solar cell connected to the substrate; a first electrical connector connected to the substrate; a first lead wire; a second electrical connector disposed at an end of the first lead wire and configured to be removably and electrically connected to the first electrical connector; and a connection box connected to an end of the first lead wire away from the second electrical connector, the connection box being configured to be electrically connected to an external device.

The embodiment of the present disclosure includes the following technical effects. In the above photovoltaic apparatus, the connection box is connected to the substrate through the first lead wire. When the connection is needed, the second electrical connector at the first lead wire is electrically connected to the first electrical connector at the substrate, in such a manner that the connection box connected to the first lead wire can be electrically connected to the solar cell, so as to facilitate the use of the connection box. At the same time, when the connection box is damaged, the second electrical connector is separated from the first electrical connector and another good connection box is used to be connected to the substrate, reducing a risk that the entire substrate cannot be used when the original connection box is damaged. Therefore, a cost is saved.

In some embodiments of the present disclosure, the photovoltaic apparatus further includes a carrying handle member connected to the substrate and having a protrusion disposed at an end of the carrying handle member, the protrusion having a first receiving cavity and a plug-in interface in communication with the first receiving cavity, and the first electrical connector being received in the first receiving cavity.

The embodiment of the present disclosure includes the following technical effects. By the above arrangement, the first electrical connector is received in the first receiving cavity, so as to reduce a risk of contact insensitivity of the first electrical connector caused by external scratches and abrasions of the first electrical connector.

In some embodiments of the present disclosure, the carrying handle member further has a carrying handle slot and a second receiving cavity, the second receiving cavity being in communication with the first receiving cavity and formed between the carrying handle slot and the first receiving cavity. The photovoltaic apparatus further includes a circuit board disposed in the second receiving cavity and electrically connected to the solar cell and the first electrical connector.

The embodiment of the present disclosure includes the following technical effects. By the above arrangement, the carrying handle slot makes it convenient for the user to carry the substrate, and at the same time, the circuit board enables the solar cell to be electrically connected to the first electrical connector.

In some embodiments of the present disclosure, the substrate has a first side edge and a second side edge adjacent to the first side edge, the protrusion being disposed at a corner where the first side edge is connected to the second side edge, and the plug-in interface at the protrusion being arranged towards the first side edge or the second side edge.

The embodiment of the present disclosure includes the following technical effects. By the above arrangement, a plug-in direction of the plug-in interface is increased to adapt to different plug-in directions of the second electrical connector.

In some embodiments of the present disclosure, the protrusion has an arc-shaped surface, the plug-in interface being formed at the arc-shaped surface.

The embodiment of the present disclosure includes the following technical effects. By the above arrangement, a risk of the plug-in interface being exposed outside the arc-shaped surface can be reduced.

In some embodiments of the present disclosure, the first receiving cavity has a side wall, the first electrical connector being formed at an end of the side wall, the plug-in interface being formed at another end of the side wall, and the side wall being configured to abut with the second electrical connector.

The embodiment of the present disclosure includes the following technical effects. By the above arrangement, a stability of the second electrical connector when inserted into the plug-in interface and connects the first electrical connector is improved.

In some embodiments of the present disclosure, the connection box comprises a main body and a second lead wire. The main body has a plurality of current output ports formed at a side wall of the main body, the plurality of current output ports being configured to supply power to an external electrical device when the first lead wire is electrically connected to the main body. The second lead wire is connected to a side of the main body away from the first lead wire. The first lead wire, the main body, and the second lead wire are electrically connected to each other. The second lead wire is provided with a third electrical connector at an end of the second lead wire away from the main body, the third electrical connector being configured to charge an external storage device when the first lead wire, the main body, and the second lead wire are electrically connected to each other.

The embodiment of the present disclosure includes the following technical effects. By the above arrangement, the external electrical device can be connected to the current output port, and the substrate can charge the external storage device by the connection box.

In some embodiments of the present disclosure, the current output port is a USB port or a Type-C port.

The embodiment of the present disclosure includes the following technical effects. By the above arrangement, a model number of the external electrical device to which the connection box can be connected can be improved.

In some embodiments of the present disclosure, the photovoltaic apparatus includes a support member rotatably connected to a side of the substrate away from the solar cell.

The embodiment of the present disclosure includes the following technical effects. By the above arrangement, the support can adjust a placement angle of the substrate while supporting the substrate and adjust an angle of the solar cell, to receive direct sunlight.

In some embodiments of the present disclosure, the substrate further has a positioning hole spaced apart from the carrying handle slot, the positioning hole being configured for passage of an external fastener to fix the substrate at a predetermined position.

The embodiment of the present disclosure includes the following technical effects. By the above arrangement, the substrate can be fixed at the predetermined position, reducing a risk of movement of the substrate in an unfolded state.

In the above photovoltaic apparatus, the connection box is connected to the substrate through the first lead wire. When the connection is needed, the second electrical connector at the first lead wire is electrically connected to the first electrical connector at the substrate, in such a manner that the connection box connected to the first lead wire can be electrically connected to the solar cell, so as to facilitate the use of the connection box. At the same time, when the connection box is damaged, the second electrical connector is separated from the first electrical connector and another good connection box is used to be connected to the substrate, reducing a risk that the entire substrate cannot be used when the original connection box is damaged. Therefore, a cost is saved.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a schematic structural view of a photovoltaic apparatus according to an embodiment of the present disclosure.

FIG. 2 is a schematic structural view of a first lead wire according to an embodiment of the present disclosure.

FIG. 3 is a schematic cross-sectional structural view taken along cross-sectional line A-A in FIG. 1.

FIG. 4 is a schematic view of an enlarged part in FIG. 3.

FIG. 5 is a schematic structural view of a connection box according to an embodiment of the present disclosure.

FIG. 6 is a schematic structural view of a support member according to an embodiment of the present disclosure.

FIG. 7 is a schematic structural view of a foldable substrate according to an embodiment of the present disclosure.

### DESCRIPTION OF REFERENCE NUMERALS OF MAIN COMPONENTS

photovoltaic apparatus 100;
substrate 10;
light-receiving surface 11;
back surface 12;
first side edge 13;
second side edge 14;
positioning hole 15;
plate body 16;
solar cell 20;
first electrical connector 30;
first lead wire 40;
second electrical connector 41;
connection box 50;
main body 51;
current output port 511;
USB port 5111;
Type-C port 5112;
second lead wire 52;
third electrical connector 521;
indicator light 53;
carrying handle member 60;
protrusion 61;
first receiving cavity 611;
side wall 6111;
plug-in interface 612;
arc-shaped surface 613;
carrying handle slot 62;
second receiving cavity 63;
bump 64;
recess 65;
support member 70.

The present disclosure will be further illustrated with reference to the above-mentioned drawings in the following specific embodiments.

### DETAILED DESCRIPTION

Technical solutions in embodiments of the present disclosure will be described with reference to the accompanying drawings in the embodiments of the present disclosure. Obviously, the described embodiments are only part of the embodiments of the present disclosure, but not all the embodiments.

It should be noted that when an assembly is described as being “mounted at” another assembly, it may be directly on another assembly or an intermediate assembly may exist. When an assembly is interpreted as being “disposed at” another assembly, it may be directly disposed at the other assembly or the intermediate assembly may exist simultaneously.

Unless otherwise defined, all technical and scientific terms used herein have the same meaning as commonly understood by those skilled in the art of the present disclosure. Terms in the present disclosure herein are only used for the purpose of describing embodiments of the present disclosure, and are not intended to limit the present disclosure. The term “and/or” as used herein includes any and all combinations of one or more related listed items. As used herein, the terms “vertical,” “horizontal,” “left,” “right,” “top,” “bottom,” and similar expressions are used for illustrative purposes only and are not intended to limit the present disclosure.

It should be understood that when describing two components as being arranged parallel/perpendicular to each other, an angle between the two components is allowed to deviate from the standard parallel/perpendicular orientation by a tolerance of ±10%.

The photovoltaic apparatus according to an embodiment of the present disclosure includes a substrate; a solar cell connected to the substrate; a first electrical connector connected to the substrate; a first lead wire; a second electrical connector disposed at an end of the first lead wire and configured to be removably and electrically connected to the first electrical connector; and a connection box connected to an end of the first lead wire away from the second electrical connector, the connection box being configured to be electrically connected to an external device.

In the above photovoltaic apparatus, the connection box is connected to the substrate through the first lead wire. When the connection is needed, the second electrical connector at the first lead wire is electrically connected to the first electrical connector at the substrate, in such a manner that the connection box connected to the first lead wire can be electrically connected to the solar cell, so as to facilitate the use of the connection box. At the same time, when the connection box is damaged, the second electrical connector is separated from the first electrical connector and another good connection box is used to be connected to the substrate, reducing a risk that the entire substrate cannot be used when the original connection box is damaged. Therefore, a cost is saved.

Some embodiments of the present disclosure will be described in detail below with reference to the accompanying drawings.

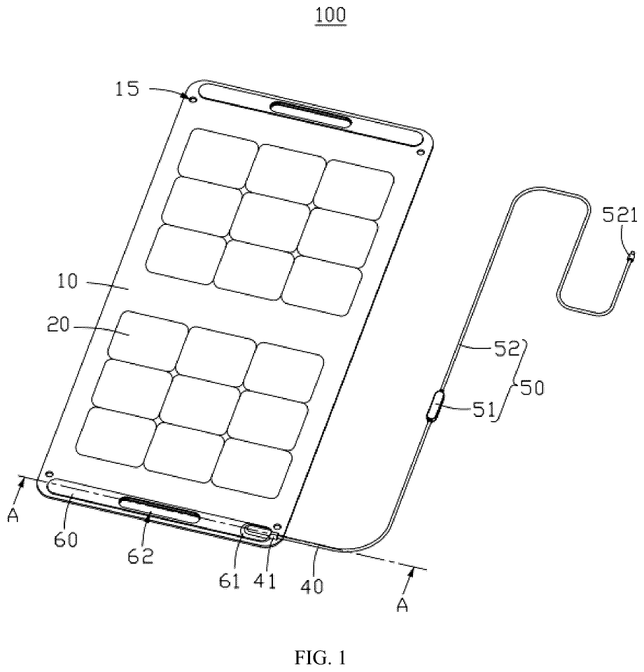

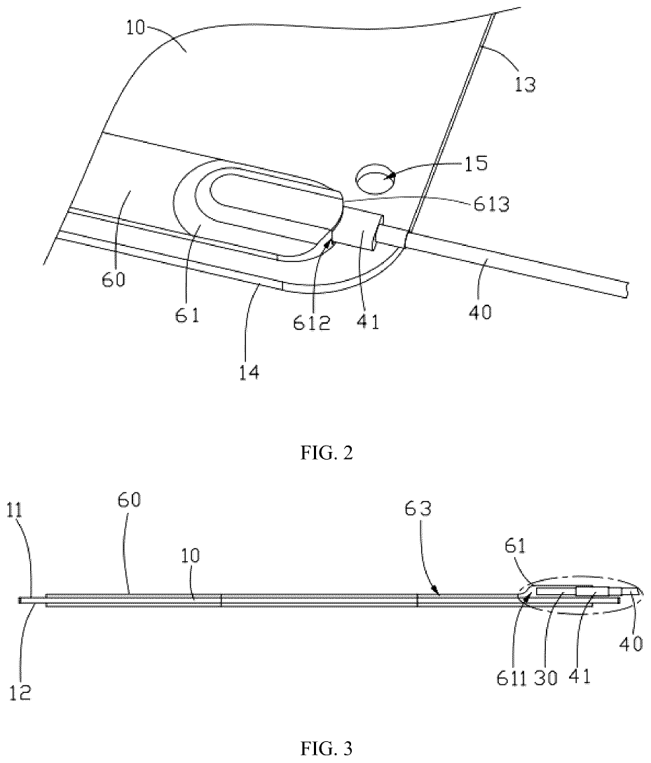

As illustrated in FIG. 1, FIG. 2, and FIG. 3, the photovoltaic apparatus 100 according to the embodiment of the present disclosure includes a substrate 10; a solar cell 20 connected to the substrate 10; a first electrical connector 30 connected to the substrate 10; a first lead wire 40 provided with a second electrical connector 41 at an end of the first lead wire 40, the second electrical connector 41 being configured to be removably and electrically connected to the first electrical connector 30; and a connection box 50 connected to an end of the first lead wire 40 away from the second electrical connector 41, the connection box 50 being configured to be electrically connected to an external device.

In the above photovoltaic apparatus 100, the connection box 50 is connected to the substrate 10 through the first lead wire 40. When the connection is needed, the second electrical connector 41 at the first lead wire 40 is electrically connected to the first electrical connector 30 at the substrate 10, in such a manner that the connection box 50 connected to the first lead wire 40 can be electrically connected to the solar cell 20, so as to facilitate the use of the connection box 50. At the same time, when the connection box 50 is damaged, the second electrical connector 41 is separated from the first electrical connector 30 and another good connection box 50 is used to be connected to the substrate 10, reducing a risk that the entire substrate 10 cannot be used when the original connection box 50 is damaged. Therefore, a cost is saved.

Further, as illustrated in FIG. 1, FIG. 2, and FIG. 3, in some embodiments, the photovoltaic apparatus 100 further includes a carrying handle member 60 connected to the substrate 10 and having a protrusion 61 disposed at an end of the carrying handle member 60. The protrusion 61 has a first receiving cavity 611 and a plug-in interface 612 in communication with the first receiving cavity 611. The first electrical connector 30 is received in the first receiving cavity 611. By the above arrangement, the first electrical connector 30 is received in the first receiving cavity 611, so as to reduce a risk of contact insensitivity of the first electrical connector caused by external scratches and abrasions of the first electrical connector 30.

As illustrated in FIG. 1, FIG. 2, and FIG. 3, in some embodiments, the carrying handle member 60 further has a carrying handle slot 62 and a second receiving cavity 63. The second receiving cavity 63 is in communication with the first receiving cavity 611 and formed between the carrying handle slot 62 and the first receiving cavity 611. The photovoltaic apparatus 100 further includes a circuit board (not illustrated) disposed in the second receiving cavity 63 and electrically connected to the solar cell 20 and the first electrical connector 30. By the above arrangement, the carrying handle slot 62 makes it convenient for the user to carry the substrate 10, and at the same time, the circuit board enables the solar cell 20 to be electrically connected to the first electrical connector 30.

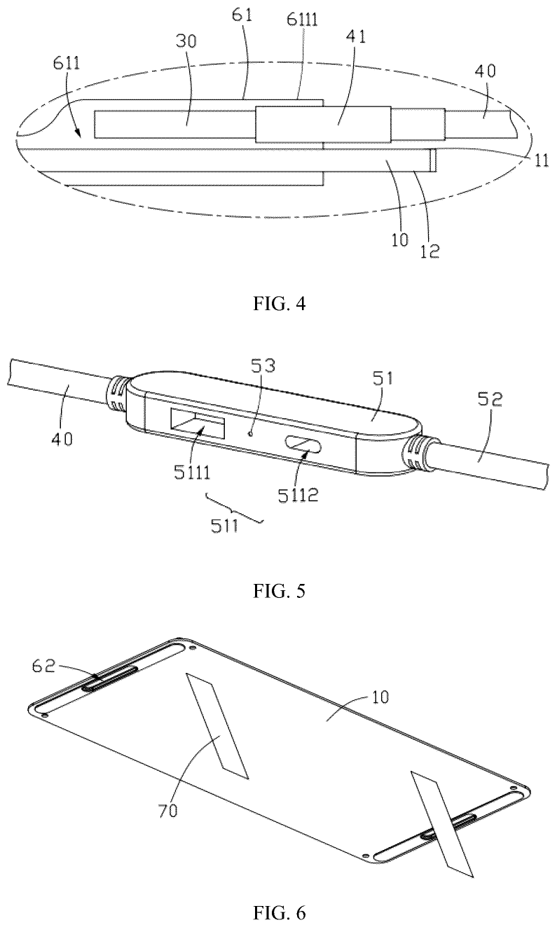

As illustrated in FIG. 3 and FIG. 4, in some embodiments, the substrate 10 has a light-receiving surface 11 and a back surface 12 opposite to the light-receiving surface 11. The protrusion 61 protrudes from the light-receiving surface 11, or from the back surface 12 so as to dispose the protrusion 61.

As illustrated in FIG. 1 and FIG. 2, in some embodiments, the substrate 10 has a first side edge 13 and a second side edge 14 adjacent to the first side edge 13. The protrusion 61 is disposed at a corner where the first side edge 13 is connected to the second side edge 14. The plug-in interface at the protrusion 61 is arranged towards the first side edge 13 or the second side edge 14. By the above arrangement, a plug-in direction of the plug-in interface 612 is increased to adapt to different plug-in directions of the second electrical connector 41.

As illustrated in FIG. 1 and FIG. 2, in some embodiments, the protrusion 61 has an arc-shaped surface 613. The plug-in interface 612 is formed at the arc-shaped surface 613, reducing a risk of the plug-in interface 612 being exposed outside the arc-shaped surface 613.

As illustrated in FIG. 3 and FIG. 4, in some embodiments, the first receiving cavity 611 has a side wall 6111. The first electrical connector 30 is formed at an end of the side wall 6111. The plug-in interface 612 is formed at another end of the side wall 6111. The side wall 6111 is configured to abut with the second electrical connector 41. In this way, a stability of the second electrical connector 41 when inserted into the plug-in interface 612 and connects the first electrical connector 30 is improved.

As illustrated in FIG. 1 and FIG. 5, in some embodiments, the connection box 50 includes a main body 51 and a second lead wire 52. The main body 51 has a plurality of current output ports 511 formed at a side wall of the main body 51. The plurality of current output ports 511 is configured to supply power to an external electrical device when the first lead wire 40 is electrically connected to the main body 51. The second lead wire 52 is connected to a side of the main body 51 away from the first lead wire 40. The first lead wire 40, the main body 51, and the second lead wire 52 are electrically connected to each other. The second lead wire 52 is provided with a third electrical connector 521 at an end of the second lead wire 52 away from the main body 51. The third electrical connector 521 is configured to charge an external storage device when the first lead wire 40, the main body 51, and the second lead wire 52 are electrically connected to each other. By the above arrangement, the external electrical device can be connected to the current output port 511, and the substrate 10 can charge the external storage device by the connection box 50.

As illustrated in FIG. 1 and FIG. 5, in some embodiments, the current output port 511 includes a USB port 5111 or a Type-C port 5112, which can improve a model number of the external electrical device to which the connection box 50 can be connected.

As illustrated in FIG. 1 and FIG. 5, in some embodiments, the connection box 50 further includes an indicator light 53 configured to display a connection state between the connection box 50 and the substrate 10 and/or a connection state between the connection box 50 and the external device.

As illustrated in FIG. 1 and FIG. 6, in some embodiments, the photovoltaic apparatus 100 includes a support member 70 rotatably connected to a side of the substrate 10 away from the solar cell 20. By the above arrangement, the support 70 can adjust a placement angle of the substrate 10 while supporting the substrate 10 and adjust an angle of the solar cell 20 to receive direct sunlight. It should be understood that the support member 70 and the substrate 10 are hingedly connected to each other, or the support member 70 and the substrate 10 are pivotally connected to each other.

As illustrated in FIG. 1 and FIG. 6, in some embodiments, the substrate 10 further has a positioning hole 15 spaced apart from the carrying handle slot 62, and the positioning hole 15 is configured for passage of an external fastener to fix the substrate 10 at a predetermined position. By the above arrangement, the substrate 10 can be fixed at the predetermined position, reducing a risk of movement of the substrate 10 in an unfolded state.

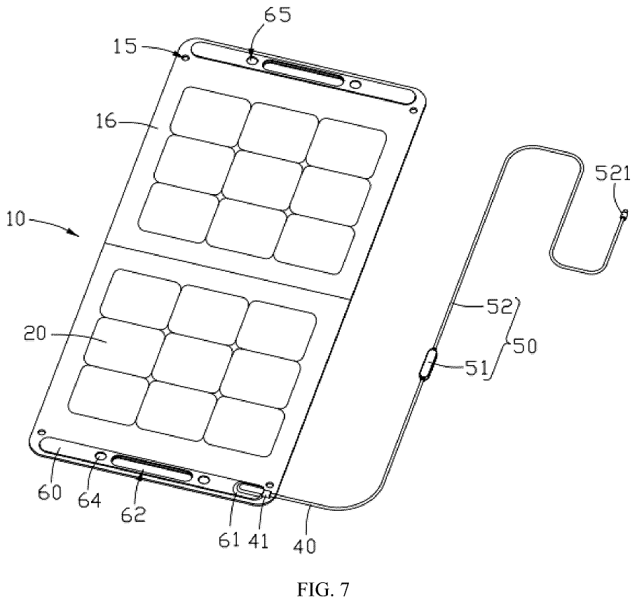

As illustrated in FIG. 1 and FIG. 7, in some embodiments, the substrate 10 includes a plurality of plate bodies 16. Adjacent plate bodies 16 are rotationally connected to each other. The substrate 10 has a folded state and an unfolded state. The adjacent plate bodies 16 are in close proximity to each other when the substrate 10 is in the folded state. When the substrate 10 is in the unfolded state, there is a predetermined angle between the adjacent plate bodies 16, and at least one solar cell 20 is disposed at each plate body 16. When in use the substrate 10 is unfolded, a light-receiving area of the solar cell 20 at the substrate 10 is increased, improving an efficiency of sunlight reception. When the substrate 10 is stored or turned around, the plate body 16 rotates towards each other into an overlapping state. Once folded, the substrate 10 occupies a relatively small volume, facilitating handling and storage.

As illustrated in FIG. 1 and FIG. 7, in this embodiment, the substrate 10 includes two plate bodies 16 rotationally connected to each other. The photovoltaic apparatus 100 includes two carrying handle members 60 disposed at an end of one plate body 16 of the two plate bodies 16 away from another plate body 16 of the two plate bodies 16, respectively. In addition, the carrying handle member 60 protrudes from a surface of the plate body 16. Each carrying handle member 60 has a carrying handle slot 62. In addition, the carrying handle slot 62 is configured to penetrate an end of the plate body 16. Two carrying handle slots 62 are configured to overlap when the substrate 10 is in the folded state. When the two plate bodies 16 are in the folded state, the two carrying handle members 60 also overlap each other, in such a manner that a user can lift the folded substrate 10 by the carrying handle slot 62, facilitating handling and transportation of a portable substrate 10. Also, the carrying handle member 60 protrudes from the surface of the plate body 16. Therefore, after the substrate 10 is folded, the two plate bodies 16 can be prevented from being in direct contact. In this way, a risk of the solar cells 20 at the two plate bodies 16 rubbing against each other can be reduced, so as to prolong service lives of the solar cells 20.

As illustrated in FIG. 1 and FIG. 7, in some embodiments, a side of each carrying handle member 60 away from the substrate 10 has a bump 64 and a recess 65 spaced apart from the bump 64. When the substrate 10 is in the folded state, the bump 64 at the carrying handle member 60, connected to one of the two plate bodies 16, extends into the recess 65, at the carrying handle member 60, connected to another of the two plate bodies 16. By the above arrangement, connection strength between the two plate bodies 16 is improved when the substrate 10 is in the folded state, reducing a risk of unfolding of the folded substrate 10 during transportation.

Those skilled in the art should recognize that the above embodiments are only used to illustrate the present disclosure, and are not intended to limit the present disclosure. As long as any modifications and variations to the above embodiments are within the spirit scope of the present disclosure, they fall within the scope of the present disclosure.

What is claimed is:

1. A photovoltaic apparatus, comprising:
a substrate;
a solar cell connected to the substrate;
a first electrical connector connected to the substrate;
a first lead wire;
a second electrical connector disposed at an end of the first lead wire and configured to be removably and electrically connected to the first electrical connector; and
a connection box connected to an end of the first lead wire away from the second electrical connector, the connection box being configured to be electrically connected to an external device.

2. The photovoltaic apparatus according to claim 1, further comprising a carrying handle member connected to the substrate and having a protrusion disposed at an end of the carrying handle member, the protrusion having a first receiving cavity and a plug-in interface in communication with the first receiving cavity, and the first electrical connector being received in the first receiving cavity.

3. The photovoltaic apparatus according to claim 2, wherein the carrying handle member has a carrying handle slot and a second receiving cavity, the second receiving cavity being in communication with the first receiving cavity and formed between the carrying handle slot and the first receiving cavity, and wherein the photovoltaic apparatus further comprises a circuit board disposed in the second receiving cavity and electrically connected to the solar cell and the first electrical connector.

4. The photovoltaic apparatus according to claim 2, wherein the substrate has a first side edge and a second side edge adjacent to the first side edge, the protrusion being disposed at a corner where the first side edge is connected to the second side edge, and the plug-in interface at the protrusion being arranged towards the first side edge or the second side edge.

5. The photovoltaic apparatus according to claim 4, wherein the protrusion has an arc-shaped surface, the plug-in interface being formed at the arc-shaped surface.

6. The photovoltaic apparatus according to claim 2, wherein the first receiving cavity has a side wall, the first electrical connector being formed at an end of the side wall, the plug-in interface being formed at another end of the side wall, and the side wall being configured to abut with the second electrical connector.

7. The photovoltaic apparatus according to claim 1, wherein the connection box comprises a main body and a second lead wire, wherein:
the main body has a plurality of current output ports formed at a side wall of the main body, the plurality of current output ports being configured to supply power to an external electrical device when the first lead wire is electrically connected to the main body;
the second lead wire is connected to a side of the main body away from the first lead wire;
the first lead wire, the main body, and the second lead wire are electrically connected to each other;
the second lead wire is provided with a third electrical connector at an end of the second lead wire away from the main body, the third electrical connector being configured to charge an external storage device when the first lead wire, the main body, and the second lead wire are electrically connected to each other.

8. The photovoltaic apparatus according to claim 7, wherein the current output port is a USB port or a Type-C port.

9. The photovoltaic apparatus according to claim 1, comprising a support member rotatably connected to a side of the substrate away from the solar cell.

10. The photovoltaic apparatus according to claim 3, wherein the substrate further has a positioning hole spaced apart from the carrying handle slot, the positioning hole being configured for passage of an external fastener to fix the substrate at a predetermined position.

11. The photovoltaic apparatus according to claim 9, wherein the substrate comprises a plurality of plate bodies, adjacent plate bodies of the plurality of plate bodies being rotationally connected to each other, to enable the substrate to be in a folded state and an unfolded state.

12. The photovoltaic apparatus according to claim 11, further comprising two carrying handle members, wherein when the substrate is in the unfolded state, the two carrying handle members are located at two opposite sides of the substrate, respectively.

13. The photovoltaic apparatus according to claim 12, wherein:
one of the two carrying handle members has a bump; and
another of the two carrying handle members has a recess,
wherein when the substrate is in the folded state, the bump is received within the recess.

14. The photovoltaic apparatus according to claim 12, further comprising an indicator light disposed at the connection box.

15. The photovoltaic apparatus according to claim 14, wherein the indicator light is configured to display a connection state between the connection box and the substrate and/or a connection state between the connection box and the external device.

16. The photovoltaic apparatus according to claim 11, wherein:
when the substrate is in the folded state, the adjacent plate bodies are in close proximity to each other; and
when the substrate is in the unfolded state, there is a predetermined angle between the adjacent plate bodies.

17. The photovoltaic apparatus according to claim 11, wherein the solar cell is disposed at the plurality of plate bodies.

18. The photovoltaic apparatus according to claim 2, wherein the substrate has a light-receiving surface and a back surface opposite to the light-receiving surface, the protrusion protruding from the light-receiving surface or from the back surface.

19. The photovoltaic apparatus according to claim 9, wherein the support member and the substrate are hingedly connected to each other.

20. The photovoltaic apparatus according to claim 9, wherein the support member and the substrate are pivotally connected to each other.
